(19) United States
(12) Patent Application Publication
(10) Pub. No.: US 2024/0224663 A1
(43) Pub. Date: Jul. 4, 2024

(54) DISPLAY DEVICE

(71) Applicant: LG Display Co., Ltd., Seoul (KR)

(72) Inventor: Geunuk KIM, Paju-si (KR)

(73) Assignee: LG Display Co., Ltd., Seoul (KR)

(21) Appl. No.: 18/518,230

(22) Filed: Nov. 22, 2023

(30) Foreign Application Priority Data
Dec. 30, 2022 (KR) 10-2022-0191102

(51) Int. Cl. H10K 59/131; G01B 7/16; G09G 3/00; H10K 59/121; H10K 59/40

(52) U.S. Cl. CPC H10K 59/131; G01B 7/22; G09G 3/006; H10K 59/1213; H10K 59/40

(57) ABSTRACT

Discussed is a display device including a substrate including an active area, a first non-active area adjacent the active area, and a second non-active area within the active area, the second non-active area including a through-hole penetrating the substrate, a plurality of light emitting elements in the active area, an encapsulation unit covering the plurality of light emitting elements, a buffer layer on the encapsulation unit, a plurality of touch electrodes on the buffer layer in the active area, a first sensing line surrounding at least a portion of the active area, and in the first non-active area, and a third sensing line disposed along an outer portion of the through-hole in the second non-active area.

### CROSS-REFERENCE TO RELATED APPLICATIONS

This application claims priority to Korean Patent Application No. 10-2022-0191102 filed on Dec. 30, 2022, in the Republic of Korea, the entire contents of which are hereby expressly incorporated by reference into the present application.

### BACKGROUND

### Technical Field

The present disclosure relates to a display device, and more particularly, to a display device capable of easily detecting defects.

### Discussion of the Related Art

Recently, with increased availability of information, a field of display devices for visually expressing an electrical information signal to express such information has rapidly advanced. Various display devices having excellent performance in terms of thinness, lightness, and low power consumption, are being developed correspondingly to provide such information.

Among various display devices, a light emitting display device is a self-luminous display device and can be manufactured to be light and thin since the light emitting display device does not require a separate light source, unlike a liquid crystal display device having a separate light source in the form of a light emitting unit. In addition, the light emitting display device has advantages in terms of power consumption due to a low voltage driving, and is excellent in terms of a color implementation, a response speed, a viewing angle, and a contrast ratio (CR). Therefore, light emitting display devices have been expected to be increasingly used in various application fields.

### SUMMARY OF THE DISCLOSURE

An object to be solved by the present disclosure is to provide a display device capable of detecting strain in a thickness direction without adding a separate component.

Another abject to be solved by the present disclosure is to provide a display device capable of detecting cracks or thickness strain according to various locations.

Objects of the present disclosure are not limited to the above-mentioned objects, and other objects, which are not mentioned above, can be clearly understood by those skilled in the art from the following descriptions.

According to an aspect of the present disclosure, a display device can include a substrate including an active area and a first non-active area surrounding the active area; a plurality of light emitting elements in the active area; an encapsulation unit covering the plurality of light emitting elements; a plurality of touch electrodes on the encapsulation unit in the active area; a first sensing line surrounding at least a portion of the active area in the first non-active area; and a second sensing line overlapping the first sensing line and configured to form a capacitor with the first sensing line.

Other detailed matters of the example embodiments are included in the detailed description and the drawings.

According to an example embodiment of the present disclosure, both crack detection and tensile strain or compression strain detection can be performed through a plurality of sensing lines overlapping each other.

According to an example embodiment of the present disclosure, it is possible to accurately determine a defect location by disposing a plurality of sensing lines overlapping each other in respective areas.

According to an embodiment of the present disclosure, a yield of a display device can be improved and process optimization can be achieved by analyzing and correcting a cause of defects. The effects according to the present disclosure are not limited to the contents exemplified above, and more various effects are included in the present specification.

### BRIEF DESCRIPTION OF THE DRAWINGS

FIG. 1 is a plan view of a display device according to an example embodiment of the present disclosure.

FIG. 2 is a cross-sectional view of II-II′ of FIG. 1 according to an example of the present disclosure.

FIG. 3 is a cross-sectional view of III-III′ of FIG. 1 according to an example of the present disclosure.

FIG. 4 is a cross-sectional view of a display device according to another example embodiment of the present disclosure.

FIG. 5 is a plan view of a display device according to still another example embodiment of the present disclosure.

FIG. 6A is an enlarged plan view of a display device according to still another example embodiment of the present disclosure.

FIG. 6B is a cross-sectional view of VIb-VIb′ of FIG. 6A according to an example of the present disclosure.

FIG. 7 is a plan view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “over”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings. All components of each display device according to all embodiments of the present disclosure are operatively coupled and configured.

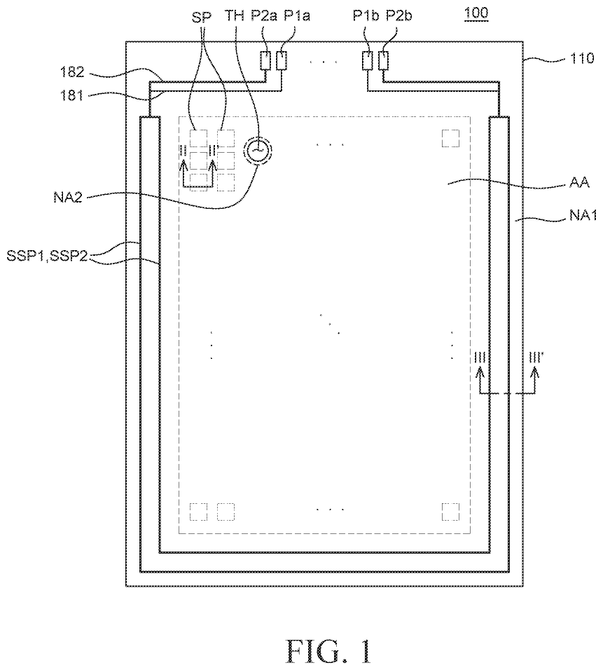

FIG. 1 is a plan view of a display device according to an example embodiment of the present disclosure. In FIG. 1, a substrate 110, a first sensing line 181, a second sensing line 182, and a plurality of sensing pads P1a, P1b, P2a, and P2b among components of a display device 100 are simply illustrated for convenience of description. In addition, to distinguish the first sensing line 181 and the second sensing line 182, the first sensing line 181 is illustrated as a line thinner than the second sensing line 182.

Referring to FIG. 1, the display device 100 according to an example embodiment of the present disclosure can include the substrate 110, the first sensing lines 181, the second sensing lines 182, and the plurality of sensing pads P1a, P1b, P2a, and P2b.

The substrate 110 is a support member for supporting other components of the display device 100 and can be formed of an insulating material. For example, the substrate 110 can be formed of glass, resin or the like. The substrate 110 can be formed to include a polymer or plastic such as polyimide (PI), or can be formed of a material having flexibility. But embodiments of the present disclosure are not limited thereto.

The substrate 110 can include an active area AA, a first non-active area NA1, and a second non-active area NA2.

The active area AA can be an area for displaying an image. A plurality of sub-pixels SP for displaying an image and a driving circuit for driving the plurality of sub-pixels SP can be disposed in the active area AA. Each of the plurality of sub-pixels SP can be an individual unit that emits light, and a light emitting element 140 to be described below can be disposed in each of the plurality of sub-pixels SP. The plurality of sub-pixels SP can include a red sub-pixel, a green sub-pixel, a blue sub-pixel, and a white sub-pixel, but are not limited thereto. The driving circuit can include various transistors, storage capacitors, lines, and the like for driving the plurality of sub-pixels SP. For example, the driving circuit can include various components such as a driving transistor, a switching transistor, a sensing transistor, a storage capacitor, gate lines, and data lines, but the present disclosure is not limited thereto.

A plurality of touch electrodes 171 and 172 to be described later, can be disposed in the active area AA. The plurality of touch electrodes 171 and 172 can include a plurality of first touch electrodes 171 and a plurality of second touch electrodes 172. The plurality of first touch electrodes 171 can extend in a first direction, and the plurality of second touch electrodes 172 can extend in a second direction. Accordingly, the plurality of first touch electrodes 171 and the plurality of second touch electrodes 172 can be disposed such that portions thereof cross each other. For example, the plurality of first touch electrodes 171 and the plurality of second touch electrodes 172 can be disposed such that portions thereof overlap each other. Accordingly, the plurality of second touch electrodes 172 can be separated from each other in overlapping areas of the first touch electrodes 171 and the second touch electrodes 172. The separated second touch electrodes 172 can be connected by a bridge pattern BP.

The plurality of touch electrodes 171 and 172 can detect a touch input that is applied to the display device 100. The touch input can be an input by a user's finger or a touch pen. For example, when a touch operation is performed on a specific area of the display device 100, a variation in capacitance can occur between the first touch electrode 171 and the second touch electrode 172 adjacent to the specific area. The display device 100 can detect touch coordinates by detecting the variation in capacitance.

The plurality of first touch electrodes 171 and the plurality of second touch electrodes 172 can have a metal mesh structure. For example, the plurality of first touch electrodes 171 and the plurality of second touch electrodes 172 can include mesh patterns formed by crossing metal lines having a very thin line width. The mesh patterns can have diamond shapes, but are not limited thereto. The mesh patterns can have a single layer or multilayer structure formed of a metal material, such as molybdenum (Mo), silver (Ag), titanium (Ti), copper (Cu), aluminum (Ti), titanium/aluminum/titanium (Ti/Al/Ti), or molybdenum/aluminum/molybdenum (Mo/Al/Mo), but are not limited thereto. Other materials can be used, such as a transparent conductive material.

Openings can be formed within the mesh patterns of the plurality of first touch electrodes 171 and the plurality of second touch electrodes 172. The opening can correspond to each of the plurality of sub-pixels SP. For example, the light emitting element 140 can be disposed in the opening.

The first non-active area NA1 is an area in which an image is not displayed, and can be disposed to surround the active area AA. The first non-active area NA1 can be an area where various lines, pads, driver ICs and the like for driving the plurality of sub-pixels SP and the plurality of touch electrodes 171 and 172 disposed in the active area AA are disposed. For example, various driver ICs such as a gate driver, a data driver, and a touch driver can be disposed in the first non-active area NA1. Also, the first non-active area NA1 can be an area in which the light emitting element 140 and the plurality of touch electrodes 171 and 172 are not disposed.

The second non-active area NA2 is an area in which an image is not displayed, and can be disposed within, or encircled by, the active area AA. The second non-active area NA2 can be an area in which the light emitting element 140 and the plurality of touch electrodes 171 and 172 are not disposed.

The second non-active area NA2 can include a through-hole TH. The through-hole TH can be a hole penetrating the substrate 110. The through-hole TH can be formed to correspond to a camera or an optical sensor, but embodiments of the present disclosure are not limited thereto.

The first sensing line 181 can be disposed to surround at least a portion of the active area AA in the first non-active area NA1. The first sensing line 181 can be disposed at an outermost portion of the first non-active area NA1 and detect whether or not a crack has occurred in the display device 100. The first sensing line 181 can be disposed at a periphery of the first non-active area NA1 without encircling the first non-active area NA1.

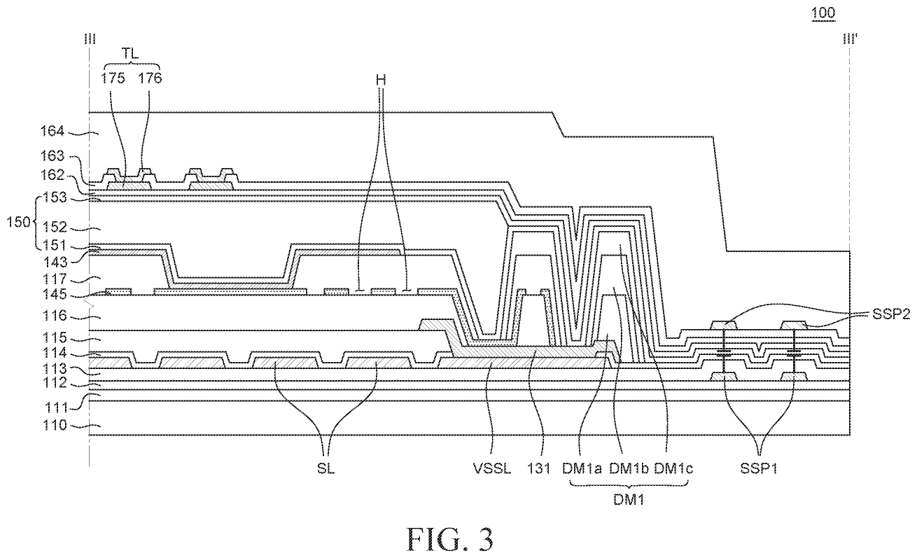

Referring to FIG. 3, a portion of the first sensing line 181 overlaps the second sensing line 182 and can be disposed below the second sensing line 182, but is not limited thereto, and locations of the first sensing line 181 and the second sensing line 182 can be switched. Although only a portion of the first sensing line 181 is illustrated in FIG. 1, a shape of a remaining portion of the first sensing line 181 can correspond to that of the second sensing line 182.

One end of the first sensing line 181 can be connected to a first-a sensing pad P1a, and the other end of the first sensing line 181 can be connected to a first-b sensing pad P1b. An area between the one end of the first sensing line 181 and the other end of the first sensing line 181 can be disposed along an outer circumference of the first non-active area NA1. For example, the first sensing line 181 can extend to the first-b sensing pad P1b from the first-a sensing pad P1a along a circumference of the substrate 110.

The area between the one end of the first sensing line 181 and the other end of the first sensing line 181 can be divided into a plurality of portions. For example, the first sensing line 181 can include two first sub-sensing portions SSP1 connected in parallel. The two first sub-sensing portions SSP1 are spaced apart by a predetermined interval and can be disposed in parallel with each other to surround the active area AA. The first sensing line 181 includes two first sub-sensing portions SSP1 connected in parallel. Thus, even if one of the two first sub-sensing portions SSP1 is disconnected, the first sensing line 181 can have a constant resistance value. Therefore, it is possible to detect whether or not a crack has occurred through the first sub-sensing portion SSP1 that is not disconnected.

FIG. 1 illustrates the first sub-sensing portions SSP1 and the second sub-sensing portions SSP2 overlapping each other for convenience of explanation. However, as illustrated in FIG. 3, the first sub-sensing portions SSP1 can be substantially disposed under the second sub-sensing portions SSP2.

The second sensing line 182 can be disposed to surround at least a portion of the active area AA in the first non-active area NA1. The second sensing line 182 can be disposed at the outermost portion of the first non-active area NA1 and detect whether or not a crack has occurred in the display device 100. The second sensing line 182 can be disposed at a periphery of the first non-active area NA1 without encircling the first non-active area NA1.

One end of the second sensing line 182 can be connected to a second-a sensing pad P2a, and the other end of the second sensing line 182 can be connected to a second-b sensing pad P2b. An area between the one end of the second sensing line 182 and the other end of the second sensing line 182 can be disposed along the outer circumference of the first non-active area NA1. For example, the second sensing line 182 can extend to the second-b sensing pad P2b from the second-a sensing pad P2a along the circumference of the substrate 110.

The area between the one end of the second sensing line 182 and the other end of the second sensing line 182 can be divided into a plurality of portions. For example, the second sensing line 182 can include two second sub-sensing portions SSP2 connected in parallel. The two second sub-sensing portions SSP2 are spaced apart by a predetermined interval and can be disposed in parallel with each other to surround the active area AA.

The second sensing line 182 includes two second sub-sensing portions SSP2 connected in parallel. Thus, even if one of the two second sub-sensing portions SSP2 is disconnected, the second sensing line 182 can have a constant resistance value. Therefore, it is possible to detect whether or not a crack has occurred through the second sub-sensing portion SSP2 that is not disconnected.

In FIG. 1, two first sub-sensing portions SSP1 and two second sub-sensing portions SSP2 are formed to surround a left side, a lower side, and a right side of the active area AA, but the present disclosure is not limited thereto. Further, the number of the sub-sensing portions SSP1 and SSP2 can be three or more, and the sensing lines 181 and 182 can be configured as single lines without the sub-sensing portions SSP1 and SSP2.

The first sensing line 181 and the second sensing line 182 can overlap each other. For example, the first sensing line 181 and the second sensing line 182 can form a capacitor. Strain in thickness direction of the display device 100 can be detected by measuring capacitance between the second sensing line 182 and the first sensing line 181.

The plurality of sensing pads P1a, P1b, P2a, and P2b can be disposed on one side of the first non-active area NA1. For example, the plurality of sensing pads P1a, P1b, P2a, and P2b can be disposed on an upper end of the first non-active area NA1, but the present disclosure is not limited thereto. An area of the first non-active area NA1 in which the plurality of sensing pads P1a, P1b, P2a, and P2b are disposed can be referred to as a pad portion. Although the plurality of sensing pads P1a, P1b, P2a, and P2b are illustrated in FIG. 1, the pad portion can further include various pads to which driving voltages or data signals are input.

A detection unit can be connected to the plurality of sensing pads P1a, P1b, P2a, and P2b. The detection unit can detect whether or not a crack has occurred by measuring resistance of the first sensing line 181 or resistance of the second sensing line 182. For example, the detection unit can input a sensing signal to the first-a sensing pad P1a and output the sensing signal to the first-b sensing pad P1b. The detection unit can include a logic circuit that measures resistances of the first sensing line 181 and the second sensing line 182 by comparing a voltage value of the input sensing signal with a voltage value of the output sensing signal. For example, the detection unit can detect a variation in resistance of the first sensing line 181 by comparing the input sensing signal with the output sensing signal, and based on this, detect a crack in the display device 100 through the first sensing line 181. This technique can also be applied to crack detection through the second sensing line 182. However, a crack detection method is not limited thereto.

The detection unit can detect strain in the thickness direction by measuring capacitance between the first sensing line 181 and the second sensing line 182. For example, the detection unit can measure the capacitance through any one of the sensing pads P1a and P1b connected to the first sensing line 181 and any one of the sensing pads P2a and P2b connected to the second sensing line 182. For example, the detection unit can input a sensing signal to the first-a sensing pad P1a and output the sensing signal to the second-a sensing pad P2a. For example, when a sensing signal of a specific voltage is applied to the first sensing line 181 through the first-a sensing pad P1a, capacitance can be generated between the first sensing line 181 and the second sensing line 182 that overlap each other. The detection unit can detect the capacitance between the first sensing line 181 and the second sensing line 182 from the sensing signal that is output through the second-a sensing pad P2a. A capacitance detection method is not limited thereto.

The capacitance can be inversely proportional to a thickness between electrodes overlapping each other. For example, when the thickness between the first sensing line 181 and the second sensing line 182 decreases due to compressive strain, the capacitance can increase. When the thickness between the first sensing line 181 and the second sensing line 182 increases due to tensile strain, the capacitance can decrease. The detection unit can detect variations in capacitance between the first sensing line 181 and the second sensing line 182 during a manufacturing process or a test process of the display device 100. Accordingly, it is possible to determine whether or not defects have occurred due to compressive strain or tensile strain of the display device 100.

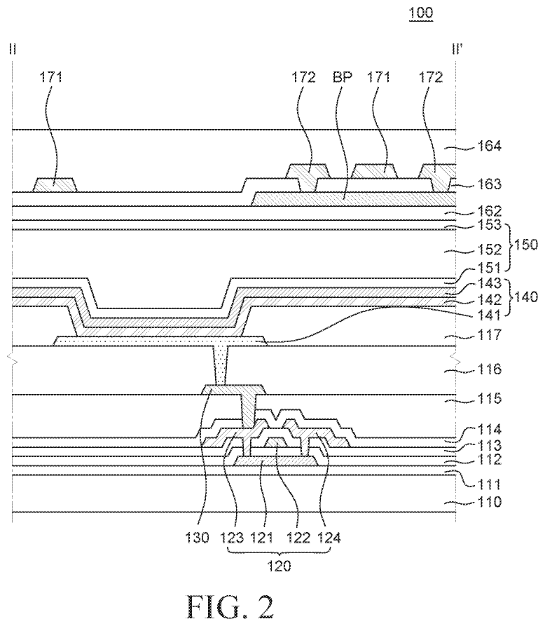

FIG. 2 is a cross-sectional view of II-II′ of FIG. 1 according to an example of the present disclosure.

Referring to FIG. 2, the display device 100 can include the substrate 110, a transistor 120, the light emitting element 140, the encapsulation unit 150, the first touch electrodes 171, and the second touch electrodes 172.

A first buffer layer 111 can be disposed on the substrate 110. The first buffer layer 111 can reduce penetration of moisture or impurities through the substrate 110. For example, the first buffer layer 111 can protect the transistor 120 from impurities such as alkali ions flowing out of the substrate 110. The first buffer layer 111 can improve adhesion between layers formed thereon and the substrate 110. The first buffer layer 111 can be formed of, for example, a single layer or multiple layers of silicon oxide (SiOx) or silicon nitride (SiNx), but is not limited thereto. But embodiments of the present disclosure are not limited thereto.

The transistor 120 can be disposed on the first buffer layer 111. The transistor 120 can drive the light emitting element 140. The transistor 120 can include an active layer 121, a gate electrode 122, a source electrode 123 and a drain electrode 124.

The active layer 121 can be disposed on the first buffer layer 111. The active layer 121 can be an area where a channel is formed when the transistor 120 is driven. The active layer 121 can include a channel region, a source region, and a drain region. The active layer 121 can be formed of a semiconductor material such as an oxide semiconductor, amorphous silicon, or polysilicon, but is not limited thereto.

A gate insulating layer 112 can be disposed on the active layer 121. The gate insulating layer 112 can insulate the active layer 121 and the gate electrode 122. Contact holes for respectively connecting the source electrode 123 and the drain electrode 124 with the active layer 121 can be formed in the gate insulating layer 112. The gate insulating layer 112 can be formed of a single layer or multiple layers of silicon oxide (SiOx) or silicon nitride (SiNx), but is not limited thereto, and other materials can be used.

The gate electrode 122 can be disposed on the gate insulating layer 112. The gate electrode 122 can be disposed on the gate insulating layer 112 to overlap the channel region of the active layer 121. The gate electrode 122 can be formed of a conductive material, such as copper (Cu), aluminum (Al), molybdenum (Mo), nickel (Ni), titanium (Ti), chromium (Cr), or an alloy thereof, but is not limited thereto, and other materials can be used, such as a transparent conductive material.

A first interlayer insulating layer 113 can be disposed on the gate electrode 122. Contact holes for respectively connecting the source electrode 123 and the drain electrode 124 to the active layer 121 can be formed in the first interlayer insulating layer 113. The first interlayer insulating layer 113 can be formed of a single layer or multiple layers of silicon oxide (SiOx) or silicon nitride (SiNx), but is not limited thereto, and other materials can be used.

The source electrode 123 and the drain electrode 124 can be disposed on the first interlayer insulating layer 113 to be spaced apart from each other. The source electrode 123 and the drain electrode 124 can be electrically connected to the active layer 121 through the contact holes of the gate insulating layer 112 and the first interlayer insulating layer 113. The source electrode 123 and the drain electrode 124 can be formed of a conductive material, such as copper (Cu), aluminum (Al), molybdenum (Mo), nickel (Ni), titanium (Ti), chromium (Cr), or an alloy thereof, but the present disclosure is not limited thereto, and other materials can be used, such as a transparent conductive material.

A passivation layer 114 can be disposed on the transistor 120. The passivation layer 114 can insulate the transistor 120 and components thereon. The passivation layer 114 can be formed of a single layer or multiple layers of silicon oxide (SiOx) or silicon nitride (SiNx), but is not limited thereto, and other materials can be used.

A first planarization layer 115 and a second planarization layer 116 can be disposed on the passivation layer 114.

The first planarization layer 115 and the second planarization layer 116 are insulating layers that planarize an upper portion of the substrate 110. The first planarization layer 115 can include a contact hole for electrically connecting the transistor 120 and a first auxiliary electrode 130 to each other. For example, the first planarization layer 115 can include a contact hole for exposing either one of the source electrode 123 and the drain electrode 124 of the transistor 120.

The second planarization layer 116 can include a contact hole for electrically connecting the first auxiliary electrode 130 and an anode 141. The first planarization layer 115 and the second planarization layer 116 can be formed of an organic material, for example, can be formed of a single layer or multilayers of polyimide or photo acrylic, but the present disclosure is not limited thereto, and other materials can be used.

The first auxiliary electrode 130 can be disposed between the first planarization layer 115 and the second planarization layer 116. The first auxiliary electrode 130 can connect the source electrode 123 of the transistor 120 and the anode 141 of the light emitting element 140.

Although the first auxiliary electrode 130 is illustrated as being connected to the source electrode 123 in FIG. 2, the first auxiliary electrode 130 can be connected to the drain electrode 124. The first auxiliary electrode 130 can be formed of a conductive material, such as copper (Cu), aluminum (Al), molybdenum (Mo), nickel (Ni), titanium (Ti), chromium (Cr), or an alloy thereof, but is not limited thereto, and other materials can be used, such as a transparent conductive material.

The light emitting element 140 can be disposed on the second planarization layer 116. The light emitting element 140 can include the anode 141, an organic layer 142, and a cathode 143.

The display device 100 can be implemented as a top emission type or a bottom emission type.

In the case of the top emission type, a reflective layer for reflecting light emitted from the organic layer 142 toward the cathode 143 can be disposed under the anode 141. For example, the reflective layer can include a material having excellent reflectivity such as aluminum (Al) or silver (Ag), but is not limited thereto, and other materials can be used, such as multiple layers of different refractive indices.

In the case of the bottom emission type, the anode 141 can be formed of a transparent conductive material. Hereinafter, descriptions are made assuming that the display device 100 according to an example embodiment of the present disclosure is the top emission type. But the inventive concept of the present disclosure is applicable to the bottom emission type as well.

The anode 141 can be disposed on the second planarization layer 116. The anode 141 can correspond to each of the plurality of sub-pixels SP. The anode 141 can be patterned to correspond to each of the plurality of sub-pixels SP one by one. The anode 141 can be electrically connected to the first auxiliary electrode 130 and the source electrode 123 of the transistor 120 through the contact holes formed in the second planarization layer 116 and the first planarization layer 115.

The anode 141 can be formed of a conductive material having a high work function in order to supply holes to the organic layer 142. For example, the anode 141 can be formed of a transparent conductive material, such as indium tin oxide (ITO) or indium zinc oxide (IZO), but is not limited thereto, and other materials can be used.

A bank 117 can be disposed on the anode 141 and the second planarization layer 116. The bank 117 can be formed on the second planarization layer 116 to cover an edge of the anode 141. The bank 117 is an insulating layer disposed between the plurality of sub-pixels to distinguish the plurality of sub-pixels. The bank 117 can be an organic insulating material. For example, the bank 117 can be formed of polyimide, acryl, or benzocyclobutene (BCB)-based resin, but is not limited thereto, and other materials can be used.

The organic layer 142 can be disposed on the anode 141 and the bank 117. The organic layer 142 can be formed as a single layer over an entire surface of the substrate 110. For example, the organic layer 142 can be a common layer that is commonly formed in the plurality of sub-pixels SP, but is not limited thereto. The organic layer 142 can be provided individually for the plurality of sub-pixels SP.

The organic layer 142 can be an organic layer for emitting light of a specific color. For example, the organic layer 142 can be one of a red light emitting layer, a green light emitting layer, a blue light emitting layer, and a white light emitting layer. When the organic layer 142 is formed of a white light emitting layer, a color filter can be further disposed on the light emitting element 140. The organic layer 142 can include various layers such as a light emitting layer, a hole transport layer, a hole injection layer, a hole blocking layer, an electron injection layer, an electron blocking layer, an electron transport layer, and the like. But embodiments of the present disclosure are not limited thereto.

The cathode 143 can be disposed on the organic layer 142. The cathode 143 can be formed as a single layer over the entire surface of the substrate 110. For example, the cathode 143 can be a common layer that is commonly formed in the plurality of sub-pixels SP. But embodiments of the present disclosure are not limited thereto, as the cathode 143 can be provided individually.

Since the cathode 143 supplies electrons to the organic layer 142, it can be formed of a conductive material having a low work function. The cathode 143 can be formed of, for example, a transparent conductive material, such as indium tin oxide (ITO) or indium zinc oxide (IZO), a metal alloy such as MgAg, or an ytterbium (Yb) alloy, and can further include a metal-doped layer, but the present disclosure is not limited thereto, and other materials can be used.

The encapsulation unit 150 can be disposed to cover the light emitting element 140. The encapsulation unit 150 protects the light emitting element 140 from moisture penetrating from the outside of the display device 100. The encapsulation unit 150 can include a first encapsulation layer 151, a foreign material cover layer 152, and a second encapsulation layer 153.

The first encapsulation layer 151 can be disposed on the cathode 143 to suppress penetration of moisture or oxygen. The first encapsulation layer 151 can be formed of an inorganic material, such as silicon nitride (SiNx), silicon oxynitride (SiNxOy), or aluminum oxide (AlyOz), but is not limited thereto, and other materials can be used.

The foreign material cover layer 152 is disposed on the first encapsulation layer 151 to planarize a surface thereof. In addition, the foreign material cover layer 152 can cover foreign materials or particles that can occur in a manufacturing process. The foreign material cover layer 152 can be formed of an organic material, such as silicon oxycarbon (SiOxCz), acrylic or epoxy-based resin, but is not limited thereto, and other materials can be used.

The second encapsulation layer 153 is disposed on the foreign material cover layer 152 and, similar to the first encapsulation layer 151, can suppress penetration of moisture or oxygen. In this case, the second encapsulation layer 153 and the first encapsulation layer 151 can be formed to seal the foreign material cover layer 152. Accordingly, moisture or oxygen penetrating into the light emitting element 140 can be more effectively reduced by the second encapsulation layer 153. The second encapsulation layer 153 can be formed of an inorganic material, such as silicon oxide (SiOx), silicon nitride (SiNx), silicon oxynitride (SiNxOy), or aluminum oxide (AlyOz), but is not limited thereto, and other materials can be used.

A second buffer layer 162 can be disposed on the encapsulation unit 150. The second buffer layer 162 can reduce penetration of moisture or impurities. The second buffer layer 162 can be formed of a single layer or multiple layers of silicon oxide (SiOx) or silicon nitride (SiNx), but is not limited thereto, and other materials can be used.

The bridge pattern BP can be disposed on the second buffer layer 162. The bridge pattern BP can electrically connect the second touch electrodes 172 that are separated. Further, the bridge pattern BP can overlap portions of the first touch electrodes 171. In this case, the bridge pattern BP can be formed on a layer different from that of the first touch electrodes 171. For example, the bridge pattern BP can be disposed below the first touch electrodes 171 that are continuously formed, and electrically connect the separated second touch electrodes 172. Accordingly, the first touch electrodes 171 and the second touch electrodes 172 that are formed to cross each other can be electrically insulated from each other.

A second interlayer insulating layer 163 can be disposed on the second buffer layer 162 and the bridge patterns BP. The second interlayer insulating layer 163 can electrically insulate the bridge pattern BP and the first touch electrode 171 from each other. The second interlayer insulating layer 163 can include a contact hole through which the second touch electrode 172 and the bridge pattern BP are connected to each other. The second interlayer insulating layer 163 can be formed of a single layer or multiple layers of silicon oxide (SiOx) or silicon nitride (SiNx), but is not limited thereto, and other materials can be used.

The first touch electrode 171 and the second touch electrode 172 can be disposed on the second interlayer insulating layer 163. The first touch electrode 171 and the second touch electrode 172 can be disposed on the second interlayer insulating layer 163 to be spaced apart from each other by a predetermined distance.

The first touch electrodes 171 can be formed to continuously extend in the first direction on the second interlayer insulating layer 163.

The second touch electrodes 172 can be formed to extend in the second direction on the second interlayer insulating layer 163. The second touch electrodes 172 can be separated in areas where they overlap the first touch electrodes 171. The separated second touch electrodes 172 can be connected by the bridge pattern BP.

A fourth planarization layer 164 can be disposed on the first touch electrodes 171, the second touch electrodes 172, and the second interlayer insulating layer 163. The fourth planarization layer 164 can planarize upper portions of the plurality of first touch electrodes 171 and the plurality of second touch electrodes 172. For example, the fourth planarization layer 164 can be configured to entirely planarize upper portions of the active area AA, the first non-active area NA1 and the second non-active area NA2 on the substrate 110. The fourth planarization layer 164 can be formed of an organic material such as silicon oxycarbon (SiOxCz), acrylic or epoxy-based resin, but is not limited thereto, and other materials can be used.

FIG. 3 is a cross-sectional view of III-III′ of FIG. 1 according to an example of the present disclosure.

Referring to FIG. 3, the display device 100 can further include a plurality of signal lines SL, a low potential power line VSSL, a second auxiliary electrode 131, a connection electrode 145, touch routing lines TL, and first dams DM1. But embodiments of the present disclosure are not limited thereto.

The plurality of signal lines SL can be disposed in the first non-active area NA1. The plurality of signal lines SL can be formed of the same material as one of various conductive components formed in the active area AA. For example, the plurality of signal lines SL can be disposed on the first interlayer insulating layer 113 and formed of the same material by the same process as the source electrode 123 and the drain electrode 124, but embodiments of the present disclosure are not limited thereto.

Various driver ICs that are electrically connected to the plurality of sub-pixels SP of the active area AA to drive the plurality of sub-pixels SP can be disposed in the first non-active area NA1. The plurality of signal lines SL can be lines that are connected to the driver IC and transmit driving signals for driving the plurality of sub-pixels SP.

The low potential power line VSSL can be disposed along the circumference of the substrate 110 at the outermost portion of the first non-active area NA1. The low potential power line VSSL can be formed of the same material as one of various conductive components formed in the active area AA. For example, the low potential power line VSSL can be disposed on the first interlayer insulating layer 113 and formed of the same material by the same process as the source electrode 123 and the drain electrode 124, but embodiments of the present disclosure are not limited thereto. The low potential power line VSSL can be electrically connected to the cathode 143 through the second auxiliary electrode 131 and the connection electrode 145. Accordingly, the low potential power line VSSL can supply a low potential voltage to the cathode 143.

The second auxiliary electrode 131 can be disposed on the low potential power line VSSL. The second auxiliary electrode 131 can be formed of the same material as one of various conductive components formed in the active area AA. For example, a portion of the second auxiliary electrode 131 can be disposed between the first planarization layer 115 and the second planarization layer 116.

The second auxiliary electrode 131 can extend on the low potential power line VSSL between the first planarization layer 115 and the second planarization layer 116. The second auxiliary electrode 131 can be formed of the same material by the same process as the first auxiliary electrode 130, but embodiments of the present disclosure are not limited thereto.

The connection electrode 145 can be disposed on the second planarization layer 116 in the first non-active area NA1. The connection electrode 145 can be formed of the same material by the same process as the anode 141, but is not limited thereto. The connection electrode 145 can be entirely formed on the second planarization layer 116 of the first non-active area NA1, but is not limited thereto.

The connection electrode 145 can be electrically connected to the cathode 143 in the first non-active area NA1. The connection electrode 145 can be electrically connected to the low potential power line VSSL by the second auxiliary electrode 131 at the outermost portion of the first non-active area NA1. Accordingly, the connection electrode 145 can supply the low potential voltage supplied through the low potential power line VSSL to the cathode 143.

The connection electrode 145 can include a plurality of holes H. Gas generated in the first planarization layer 115 or the second planarization layer 116 under the connection electrode 145 during the manufacturing process can be easily discharged to the outside through the plurality of holes H.

The touch routing line TL can be disposed on the second buffer layer 162 in the first non-active area NA1. A plurality of the touch routing lines TL can be provided and electrically connected to each of the plurality of first touch electrodes 171 and the plurality of second touch electrodes 172. One ends of the touch routing lines TL can be connected to the plurality of first touch electrodes 171 or the plurality of second touch electrodes 172 and the other ends of the touch routing lines TL can be connected to touch pads. Accordingly, the touch routing line TL can receive a touch signal from the outside or transmit a touch sensing signal to the outside.

The touch routing line TL can include a first line layer 175 and a second line layer 176. Since the touch routing line TL has a structure in which the first line layer 175 and the second line layer 176 are stacked, resistance of the lines can be reduced.

The first line layer 175 can be disposed on the second buffer layer 162. The first line layer 175 can be formed of the same material by the same process as the bridge pattern BP. But embodiments of the present disclosure are not limited thereto.

The second line layer 176 can be disposed on the first line layer 175. The second line layer 176 can be electrically connected to the first line layer 175 through a contact hole formed in the second interlayer insulating layer 163. The second line layer 176 can be formed of the same material by the same process as the first touch electrode 171 and the second touch electrode 172. But embodiments of the present disclosure are not limited thereto.

The first dam DM1 can be disposed in an area adjacent to an end portion of the substrate 110. The first dam DM1 can be disposed to surround the active area AA in the first non-active area NA1. The first dam DM1 can be disposed to overlap the low potential power line VSSL or the second auxiliary electrode 131, but is not limited thereto. In addition, although FIG. 3 illustrates that two first dams DM1 are provided, the present disclosure is not limited thereto, and the number of the first dams DM1 can be changed as needed.

The first dams DM1 can prevent overflow of the foreign material cover layer 152. The first dam DM1 can have a structure in which a first layer DM1a, a second layer DM1b, and a third layer DM1c are stacked. But embodiments of the present disclosure are not limited thereto.

The first layer DM1a can be formed of the same material by the same process as the second planarization layer 116, but is not limited thereto. The second layer DM1b can be formed of the same material by the same process as the bank 117, but is not limited thereto. The third layer DM1c can be formed of an organic material, and can be formed of polyimide, acryl, or benzocyclobutene (BCB)-based resin, but is not limited thereto.

The first sensing line 181 and the second sensing line 182 can be disposed adjacent to the end portion of the substrate 110. The first sensing line 181 and the second sensing line 182 can be disposed outside the first dams DM1. In addition, the first sensing line 181 and the second sensing line 182 can be disposed outside the low potential power line VSSL.

The first sensing line 181 can be formed of the same material as one of various conductive components formed in the active area AA. For example, the first sensing line 181 can be formed on the gate insulating layer 112 and formed of the same material by the same process as the gate electrode 122, but is not limited thereto. Accordingly, the first sensing line 181 can detect cracks generated in layers such as the substrate 110, the first buffer layer 111, the gate insulating layer 112, the interlayer insulating layer 113, and the passivation layer 114 that are adjacent to the first sensing line 181, but embodiments of the present disclosure are not limited thereto. For example, the first sensing line 181 can be formed by the same process as other conductive components other than the gate electrode 122, but is not limited thereto.

The second sensing line 182 can be formed of the same material as one of various conductive components formed in the active area AA. For example, the second sensing line 182 can be formed on the second interlayer insulating layer 163 and formed of the same material by the same process as the first touch electrode 171, the second touch electrode 172, and the second line layer 176. But embodiments of the present disclosure are not limited thereto. Accordingly, the second sensing line 182 can detect cracks generated in layers such as the first encapsulation layer 151, the second encapsulation layer 153, the second buffer layer 162, and the second interlayer insulating layer 163 that are adjacent to the second sensing line 182, but embodiments of the present disclosure are not limited thereto. For example, the second sensing line 182 can be formed by the same process as other conductive components other than the first touch electrode 171, the second touch electrode 172, and the second line layer 176, but is not limited thereto.

At least a portion of the first sensing line 181 and the second sensing line 182 can be disposed to overlap each other. For example, as illustrated in FIG. 1, the first sensing line 181 and the second sensing line 182 can be disposed to overlap each other in a remaining area except for an upper side of the first non-active area NA1 including the pad portion. For example, as illustrated in FIG. 3, a plurality of the first sub-sensing portions SSP1 of the first sensing line 181 and a plurality of the second sub-sensing portions SSP2 of the second sensing line 182 overlap each other.

A plurality of inorganic insulating layers can be disposed between the plurality of first sub-sensing portions SSP1 and the plurality of second sub-sensing portions SSP2 overlapping each other. Accordingly, the first sensing line 181 and the second sensing line 182 can form a capacitor, and capacitance can occur between the first sensing line 181 and the second sensing line 182. Accordingly, strain in the thickness direction of the display device 100 can be detected by detecting variations in capacitance between the first sensing line 181 and the second sensing line 182.

FIG. 3 illustrates that the first buffer layer 111, the gate insulating layer 112, the interlayer insulating layer 113, the passivation layer 114, the first encapsulation layer 151, the second encapsulation layer 153, the second buffer layer 162, and the second interlayer insulating layer 163 are disposed between the first sub-sensing portions SSP1 and the second sub-sensing portions SSP2, but the present disclosure is not limited thereto. For example, a portion of the first buffer layer 111, the gate insulating layer 112, the interlayer insulating layer 113, the passivation layer 114, the first encapsulation layer 151, the second encapsulation layer 153, the second buffer layer 162, and the second interlayer insulating layer 163 may not be formed up to the end portion of the substrate 110, but can be formed up to an inner side of the end portion of the substrate 110.

The display device can be exposed to various environments during a manufacturing process, and defects can occur therein. Defects that can occur in the display device include cracks, thickness strain due to compression or tension, and the like. In particular, when compressive strain occurs in a local area, overall flatness and display quality of the display device can be degraded due to pressing. In addition, when tensile strain occurs, separation between components of the display device can occur, and due to the separation or delamination, warping, or moisture permeation can occur and reliability can be degraded.

The inventors of the present disclosure have recognized the defects aforementioned and have conducted various studies and experiments to detect a local area where compressive strain of the display device occurs. Through various studies and tests, they have invented a display device capable of having improved display quality by easily detecting cracks in a local area where compressive strain occurs. This will be explained below.

The display device 100 according to an example embodiment of the present disclosure can include the first sensing line 181 and the second sensing line 182. The first sensing line 181 and the second sensing line 182 can be disposed along the circumference of the substrate 110 at the outer circumference of the first non-active area NA1. Accordingly, cracks generated in the display device 100 can be easily detected.

The first sensing line 181 and the second sensing line 182 can be disposed on different layers. For example, the second sensing line 182 can be disposed above the first sensing line 181. Thus, cracks occurring in different areas can be easily detected. Further, the first sensing line 181 and the second sensing line 182 can overlap each other. Accordingly, cracks in an increased area can be detected while a bezel size is minimized.

The first sensing line 181 and the second sensing line 182 overlapping each other can form a capacitor. For example, strain in a thickness direction between the first sensing line 181 and the second sensing line 182 can be detected by detecting a variation in capacitance between the first sensing line 181 and the second sensing line 182. For example, when the capacitance increases, it means that a distance between the first sensing line 181 and the second sensing line 182 decreases, and thus, it is possible to detect that compressive strain has occurred. In addition, when the capacitance decreases, it means that the distance between the first sensing line 181 and the second sensing line 182 increases, and thus, it is possible to detect that tensile strain has occurred.

The display device 100 can detect strain in the thickness direction as well as cracks through the first sensing line 181 and the second sensing line 182. For example, it is not necessary to separately form a structure for crack detection and a structure for capacitance detection. Accordingly, a structure of the display device 100 can be simplified and a size of the display device 100 can be reduced.

The display device 100 according to an example embodiment of the present disclosure can easily detect cracks and strain in the thickness direction during a manufacturing process of the display device 100 or after the manufacturing process of the display device 100 is completed. Accordingly, a yield of the display device 100 can be improved by analyzing and correcting a cause of a defect. In addition, quality of the display device 100 can be improved by preventing a decrease in flatness due to local pressing of the display device 100 and moisture permeation due to the separation thereof.

The display device 100 according to an example embodiment of the present disclosure can further include a compensation capacitor. The compensation capacitor can be disposed in an area of the display device 100 in which thickness strain due to compression or tension hardly occurs. By the compensation capacitor, it is possible to determine whether a variation in capacitance between the first sensing line 181 and the second sensing line 182 is influenced by temperature or humidity. For example, the display device 100 can more clearly detect a cause of the thickness stain by further including the compensation capacitor. The display device 100 can include at least one compensation capacitor, but is not limited thereto, and the compensation capacitor can be omitted in some cases.

The capacitance can be proportional to permittivity of a dielectric between electrodes constituting the capacitor. At this time, the permittivity can be affected by temperature and humidity. Since the compensation capacitor is disposed in an area in which thickness strain due to compression or tension hardly occurs, the capacitance of the compensation capacitor can change due to a change in temperature or humidity. Therefore, when there is no variation in capacitance of the compensation capacitor and there is only a variation in capacitance between the first sensing line 181 and the second sensing line 182, the detection unit can detect that compressive strain or tensile strain has occurred in the display device 100. If a variation in capacitance occurs in both the compensation capacitor and between the first sensing line 181 and the second sensing line 182, the detection unit can determine whether the variation in capacitance is due to temperature or humidity, or is due to all of temperature, humidity, compressive strain, and tensile strain.

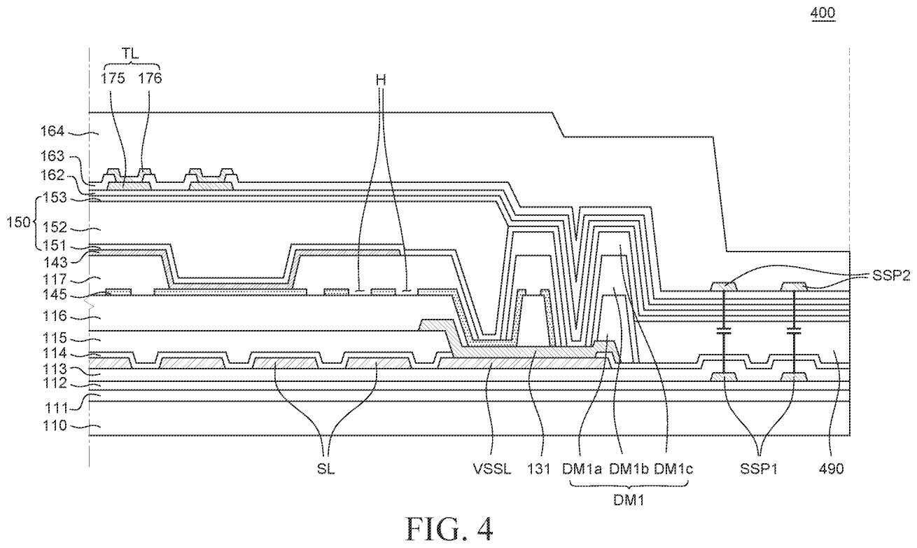

FIG. 4 is a cross-sectional view of a display device according to another example embodiment of the present disclosure. Since other configurations of a display device 400 in FIG. 4 are substantially identical to those of the display device 100 of FIGS. 1 to 3 with only a difference in a dielectric layer 490, redundant descriptions will be omitted or briefly provided.

Referring to FIG. 4, the display device 400 can further include the dielectric layer 490.

The dielectric layer 490 can be disposed between the first sensing line 181 and the second sensing line 182. For example, the dielectric layer 490 can be disposed between the first sub-sensing portion SSP1 and the second sub-sensing portion SSP2 overlapping each other.

The dielectric layer 490 can extend from an outer portion of the first dams DM1 to the end portion of the substrate 110. For example, a side surface of the dielectric layer 490 can be disposed on the same line as a side surface of the substrate 110. The dielectric layer 490 can be disposed between the passivation layer 114 and the first encapsulation layer 151, but is not limited thereto.

The display device 400 according to another example embodiment of the present disclosure can include the first sensing line 181 and the second sensing line 182 overlapping each other. The display device 400 can detect cracks and strain in the thickness direction through the first sensing line 181 and the second sensing line 182.

The display device 400 can include the dielectric layer 490 disposed between the first sensing line 181 and the second sensing line 182. Accordingly, the capacitance between the first sensing line 181 and the second sensing line 182 can be more accurately detected.

For example, the dielectric layer 490 allows a capacitance value between the first sensing line 181 and the second sensing line 182 to be configured within an appropriate range. For example, when the first sensing line 181 and the second sensing line 182 are disposed too close to each other, strain in the thickness direction may not be sufficiently made. Further, since the capacitance value that is measured, and is too large, a variation in capacitance value can be inaccurately detected. Alternatively, when the first sensing line 181 and the second sensing line 182 are disposed too far apart from each other, the measured capacitance value is too small, and thus, a variation in capacitance value can be inaccurately detected. Accordingly, the display device 400 can be configured such that the first sensing line 181 and the second sensing line 182 have an appropriate separation distance through the dielectric layer 490. Further, the display device 400 can be configured such that the first sensing line 181 and the second sensing line 182 have an appropriate capacitance value through the dielectric layer 490. Accordingly, accuracy of detecting defects of the display device 100 can be improved.

FIG. 4 provides that the first sensing line 181 and the second sensing line 182 have an appropriate separation distance through the dielectric layer 490, but embodiments of the present disclosure are not limited thereto. For example, the appropriate separation distance between the first sensing line 181 and the second sensing line 182 can be provided by a combination of the dielectric layer 490 and various other layers interposed between the sensing lines 181 and the sensing line 182 in the thickness direction of the display device 400. For example, the thickness of one or more of the individual layers, such as the interlayer insulating layer 113, the passivation layer 114, the first encapsulation layer 151, the second encapsulation layer 153, the second interlayer insulating layer 163 and the fourth planarization layer 164 can be adjusted along with the dielectric layer 490 to provide the appropriate separation distance between the first sensing line 181 and the second sensing line 182. In other embodiments of the present disclosure, only a thickness of least one of the interlayer insulating layer 113, the passivation layer 114, the first encapsulation layer 151, the second encapsulation layer 153, the second interlayer insulating layer 163 and the fourth planarization layer 164 need be adjusted to provide a calibrated capacitance between the first sensing line 181 and the second sensing line 182, and the dielectric layer 490 can be absent as shown in FIG. 3.

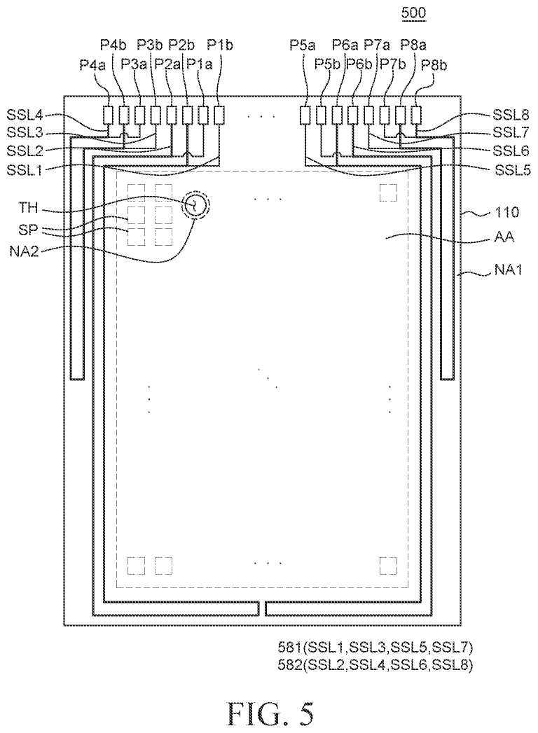

FIG. 5 is a plan view of a display device according to still another example embodiment of the present disclosure. In FIG. 5, a first sensing line 581 is illustrated as a line that is thinner than a second sensing line 582 in order to distinguish the first sensing line 581 and the second sensing line 582. Since other configurations of a display device 500 in FIG. 5 are substantially identical to those of the display device 100 of FIGS. 1 to 3 with only differences in the first sensing line 581, the second sensing line 582, and a plurality of sensing pads P1a, P1b, P2a, P2b, P3a, P3b, P4a, P4b, P5a, P5b, P6a, P6b, P7a, P7b, P8a, and P8b, redundant descriptions will be omitted or briefly provided.

Referring to FIG. 5, the display device 500 can include the first sensing line 581, the second sensing line 582, and the plurality of sensing pads P1a, P1b, P2a, P2b, P3a, P3b, P4a, P4b, P5a, P5b, P6a, P6b, P7a, P7b, P8a, and P8b, but is not limited thereto.

The first sensing line 581 can be disposed at the outermost portion of the first non-active area NA1 and detect whether or not a crack has occurred in the display device 500. The first sensing line 581 can include a plurality of sub-sensing lines SSL1, SSL3, SSL5, and SSL7 that are spaced apart from each other. The plurality of sub-sensing lines SSL1, SSL3, SSL5, and SSL7 can include a first sub-sensing line SSL1, a third sub-sensing line SSL3, a fifth sub-sensing line SSL5, and a seventh sub-sensing line SSL7.

Referring to FIG. 5, portions of the first sub-sensing line SSL1, the third sub-sensing line SSL3, the fifth sub-sensing line SSL5, and the seventh sub-sensing line SSL7 can overlap a second sub-sensing line SSL2, a fourth sub-sensing line SSL4, a sixth sub-sensing line SSL6, and an eighth sub-sensing line SSL8, respectively, and can be disposed below them. In FIG. 5, only portions of the first sub-sensing line SSL1, the third sub-sensing line SSL3, the fifth sub-sensing line SSL5, and the seventh sub-sensing line SSL7 are illustrated, but shapes of remaining portions thereof can correspond to those of the second sub-sensing line SSL2, the fourth sub-sensing line SSL4, the sixth sub-sensing line SSL6, and the eighth sub-sensing line SSL8.

Each of the plurality of sub-sensing lines SSL1, SSL3, SSL5, and SSL7 can be disposed to surround at least a portion of the active area AA in the first non-active area NA1. The first sub-sensing line SSL1 and the fifth sub-sensing line SSL5 can have symmetrical shapes, and the third sub-sensing line SSL3 and the seventh sub-sensing line SSL7 can have symmetrical shapes.

For example, the first sub-sensing line SSL1 can be disposed to extend to an opposite side of a pad portion at one side of the first non-active area NA1. For example, the first sub-sensing line SSL1 can be disposed on a left side of the first non-active area NA1 and can be disposed to surround a portion of an upper side, a left side, and a portion of a lower side of the active area AA.

The third sub-sensing line SSL3 can be disposed to surround a portion of the active area AA at the one side of the first non-active area NA1. For example, the third sub-sensing line SSL3 can be disposed on a left side of the first non-active area NA1 and can be disposed to surround a portion of the upper side and a portion of the left side of the active area AA.

The fifth sub-sensing line SSL5 can be disposed to extend to the opposite side of the pad portion at the other side of the first non-active area NA1. For example, the fifth sub-sensing line SSL5 can be disposed on a right side of the first non-active area NA1 and can be disposed to surround a portion of the upper side, the right side, and a portion of the lower side of the active area AA.

The seventh sub-sensing line SSL7 can be disposed to surround a portion of the active area AA at the other side of the first non-active area NA1. For example, the seventh sub-sensing line SSL7 can be disposed on the right side of the first non-active area NA1 and can be disposed to surround a portion of the upper side and a portion of the right side of the active area AA. However, shapes of the plurality of sub-sensing lines SSL1, SSL3, SSL5, and SSL7 are not limited thereto.

Each of one ends and the other ends of the first sub-sensing line SSL1, the third sub-sensing line SSL3, the fifth sub-sensing line SSL5, and the seventh sub-sensing line SSL7 can be connected to different sensing pads P1a, P1b, P3a, P3b, P5a, P5b, P7a, and P7b.

For example, one end of the first sub-sensing line SSL1 can be connected to a first-a sensing pad P1a and the other end thereof can be connected to a first-b sensing pad P1b. One end of the third sub-sensing line SSL3 can be connected to a third-a sensing pad P3a and the other end thereof can be connected to a third-b sensing pad P3b. One end of the fifth sub-sensing line SSL5 can be connected to a fifth-a sensing pad P5a and the other end thereof can be connected to a fifth-b sensing pad P5b. One end of the seventh sub-sensing line SSL7 can be connected to a seventh-a sensing pad P7a and the other end thereof can be connected to a seventh-b sensing pad P7b.

The first sub-sensing line SSL1, the third sub-sensing line SSL3, the fifth sub-sensing line SSL5, and the seventh sub-sensing line SSL7 can be respectively connected to the different sensing pads P1a, P1b, P3a, P3b, P5a, P5b, P7a, and P7b and can be disposed in different areas. Accordingly, the display device 500 can detect not only whether a crack has occurred but also detect a location where the crack has occurred.

For example, when a variation in resistance is detected only in the first sub-sensing line SSL1, the detection unit can detect that a crack has occurred in a lower left portion of the display device 500 where the first sub-sensing line SSL1 is disposed. For example, only the first sub-sensing line SSL1 can be disposed on the lower left portion of the display device 500. Accordingly, when a crack has occurred in the lower left portion, disconnection occurs only in the first sub-sensing line SSL1, and a variation in resistance can be detected in the first sub-sensing line SSL1.

Since the first sub-sensing line SSL1 extends from an upper left portion to the lower left portion, resistance can be changed not only by the crack in the lower left portion but also by a crack in the upper left portion. For example, when a variation in resistance is simultaneously detected in the first sub-sensing line SSL1 and the third sub-sensing line SSL3, it is possible to determine whether a crack has occurred only in the upper left portion or in all the upper left portion and the lower left portion, by comparing respective variation values. For example, by comparing variation values in resistance of the first sub-sensing line SSL1 and the third sub-sensing line SSL3, it is possible to detect an area where a crack has occurred more severely.

The third sub-sensing line SSL3 can be disposed outside the first sub-sensing line SSL1. For example, the sensing line extending to the opposite side of the pad portion can be located inside the sensing line extending to a central portion of the active area AA. Accordingly, detection accuracy at an upper portion of the display device 500 can be improved.

Cracks occurring in the display device 500 can generally occur in the outer circumference of the first non-active area NA1. When the first sub-sensing line SSL1 and the third sub-sensing line SSL3 are formed in an opposite manner and cracks may be minutely generated only in a part of the outer circumference of the first non-active area NA1, disconnection can be generated only in the first sub-sensing line SSL1 and may not be generated in the third sub-sensing line SSL3.

At this time, since the first sub-sensing line SSL1 extends to the lower left portion of the display device, the detection unit can determine that a crack has occurred in the lower left portion. For example, an area where a crack actually occurs is the upper left portion, but a normal signal can be detected in the third sub-sensing line SSL3, so there can occur an error in detecting a location of the crack. Accordingly, by disposing the third sub-sensing line SSL3 outside the first sub-sensing line SSL1, it is possible to prevent an error from occurring in detecting a crack location. But embodiments of the present disclosure are not limited thereto, and the location of the third sub-sensing line SSL3 and the first sub-sensing line SSL1 can be switched.

The detection method described above can be equally applied to the fifth sub-sensing line SSL5 and the seventh sub-sensing line SSL7, and the detection method of the present disclosure is not limited thereto.

The second sensing line 582 can be disposed at the outermost portion of the first non-active area NA1 and detect whether or not a crack has occurred in the display device 500. The second sensing line 582 can include a plurality of sub-sensing lines SSL2, SSL4, SSL6, and SSL8 that are spaced apart from each other. The plurality of sub-sensing lines SSL2, SSL4, SSL6, and SSL8 include a second sub-sensing line SSL2, a fourth sub-sensing line SSL4, a sixth sub-sensing line SSL6, and an eighth sub-sensing line SSL8.

Each of the plurality of sub-sensing lines SSL2, SSL4, SSL6, and SSL8 can be disposed to surround at least a portion of the active area AA in the first non-active area NA1. The second sub-sensing line SSL2 and the sixth sub-sensing line SSL6 can have symmetrical shapes, and the fourth sub-sensing line SSL4 and the eighth sub-sensing line SSL8 can have symmetrical shapes.

For example, the second sub-sensing line SSL2 can overlap the first sub-sensing line SSL1 and extend to the opposite side of the pad portion at one side of the first non-active area NA1. The fourth sub-sensing line SSL4 can overlap the third sub-sensing line SSL3 and can be disposed to surround a portion of the active area AA at the one side of the first non-active area NA1. The sixth sub-sensing line SSL6 can overlap the fifth sub-sensing line SSL5 and can be disposed to extend to the opposite side of the pad portion at the other side of the first non-active area NA1. The eighth sub-sensing line SSL8 can overlap the seventh sub-sensing line SSL7 and can be disposed to surround a portion of the active area AA at the other side of the first non-active area NA1. However, shapes of the plurality of sub-sensing lines SSL2, SSL4, SSL6, and SSL8 are not limited thereto.

Each of one ends and the other ends of the second sub-sensing line SSL2, the fourth sub-sensing line SSL4, the sixth sub-sensing line SSL6, and the eighth sub-sensing line SSL8 can be connected to different sensing pads P2a, P2b, P4a, P4b, P6a, P6b, P8a, and P8b.

For example, one end of the second sub-sensing line SSL2 can be connected to a second-a sensing pad P2a and the other end thereof can be connected to a second-b sensing pad P2b. One end of the fourth sub-sensing line SSL4 can be connected to a fourth-a sensing pad P4a and the other end thereof can be connected to a fourth-b sensing pad P4b. One end of the sixth sub-sensing line SSL6 can be connected to a sixth-a sensing pad P6a and the other end thereof can be connected to a sixth-b sensing pad P6b. One end of the eighth sub-sensing line SSL8 can be connected to an eighth-a sensing pad P8a and the other end thereof can be connected to an eighth-b sensing pad P8b.

The second sub-sensing line SSL2, the fourth sub-sensing line SSL4, the sixth sub-sensing line SSL6, and the eighth sub-sensing line SSL8 can be respectively connected to different sensing pads P2a, P2b, P4a, P4b, P6a, P6b, P8a, and P8b, and can be disposed in different areas. Accordingly, the display device 500 can detect not only whether or not a crack has occurred but also a location where the crack has occurred. For example, for the second sub-sensing line SSL2, the fourth sub-sensing line SSL4, the sixth sub-sensing line SSL6, and the eighth sub-sensing line SSL8, it is possible to detect whether or not a crack has occurred and a location where the crack has occurred by a detection method similar to that of the third sub-sensing line SSL3, the fifth sub-sensing line SSL5, and the seventh sub-sensing line SSL7 described above.

The first sensing line 581 and the second sensing line 582 can overlap each other. For example, the first sensing line 581 can be disposed below the second sensing line 582, but is not limited thereto, and locations of the first sensing line 581 and the second sensing line 582 can be switched. Accordingly, the first sensing line 581 can detect cracks generated in lower layers of the display device 500 that are adjacent to the substrate 110. Further, the second sensing line 582 can detect cracks generated in upper layers of the display device 500 that are adjacent to the first encapsulation layer 151 and the second encapsulation layer 153.

Since the first sensing line 581 and the second sensing line 582 overlap each other, the first sensing line 581 and the second sensing line 582 can form a capacitor. The detection unit can detect strain in a thickness direction of the display device 500 by measuring a capacitance between the second sensing line 582 and the first sensing line 581. For example, since the plurality of sub-sensing lines SSL1, SSL2, SSL3, SSL4, SSL5, SSL6, SSL7 and SSL8 are disposed in different areas, the display device 500 can detect not only whether or not thickness strain occurs but also detect a location where the thickness strain has occurred.

For example, the detection unit can measure the capacitance through one of the sensing pads P1a and P1b connected to the first sub-sensing line SSL1 and one of the sensing pads P2a and P2b connected to the second sub-sensing line SSL2. Through the measured capacitance, it is possible to detect strain in the thickness direction of the lower left portion of the display device 500 on which the first sub-sensing line SSL1 and the second sub-sensing line SSL2 are disposed.

The detection unit can measure the capacitance through one of the sensing pads P3a and P3b connected to the third sub-sensing line SSL3 and one of the sensing pads P4a and P4b connected to the fourth sub-sensing line SSL4. Through the measured capacitance, it is possible to detect strain in the thickness direction of the upper left portion of the display device 500 on which the third sub-sensing line SSL3 and the fourth sub-sensing line SSL4 are disposed.

The detection unit can measure the capacitance through one of the sensing pads P5a and P5b connected to the fifth sub-sensing line SSL5 and one of the sensing pads P6a and P6b connected to the sixth sub-sensing line SSL6. Through the measured capacitance, it is possible to detect strain in the thickness direction of a lower right portion of the display device 500 on which the fifth sub-sensing line SSL5 and the sixth sub-sensing line SSL6 are disposed.

The detection unit can measure the capacitance through one of the sensing pads P7a and P7b connected to the seventh sub-sensing line SSL7 and one of the sensing pads P8a and P8b connected to the eighth sub-sensing line SSL8. Through the measured capacitance, it is possible to detect strain in the thickness direction of an upper right portion of the display device 500 on which the seventh sub-sensing line SSL7 and the eighth sub-sensing line SSL8 are disposed.

The display device 500 according to still another example embodiment of the present disclosure can include the first sensing line 581 and the second sensing line 582 overlapping each other. The display device 500 can detect cracks and strain in the thickness direction through the first sensing line 581 and the second sensing line 582.

In particular, the first sensing line 581 can include the plurality of sub-sensing lines SSL1, SSL3, SSL5, and SSL7, and the second sensing line 582 can include the plurality of sub-sensing lines SSL2, SSL4, SSL6, and SSL8.

The plurality of sub-sensing lines SSL1, SSL3, SSL5, and SSL7 of the first sensing line 581 and the plurality of sub-sensing lines SSL2, SSL4, SSL6, and SSL8 of the second sensing line 582 can be respectively connected to different sensing pads P1a, P1b, P2a, and P2b, P3a, P3b, P4a, P4b, P5a, P5b, P6a, P6b, P7a, P7b, P8a, and P8b and can be disposed in different areas of the display device 500. For example, the display device 500 can detect locations where a crack or thickness strain occurs, together. Accordingly, accuracy of detecting defects of the display device 500 can be improved. In addition, by analyzing and correcting the cause of the defect, more contribution can be made to improving a yield and quality of the display device 500.

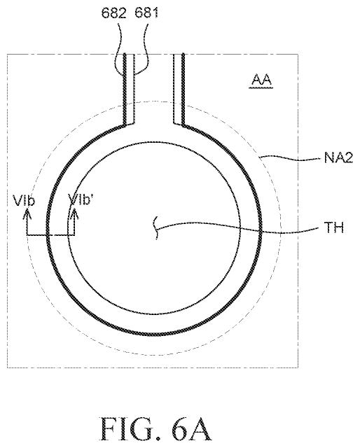

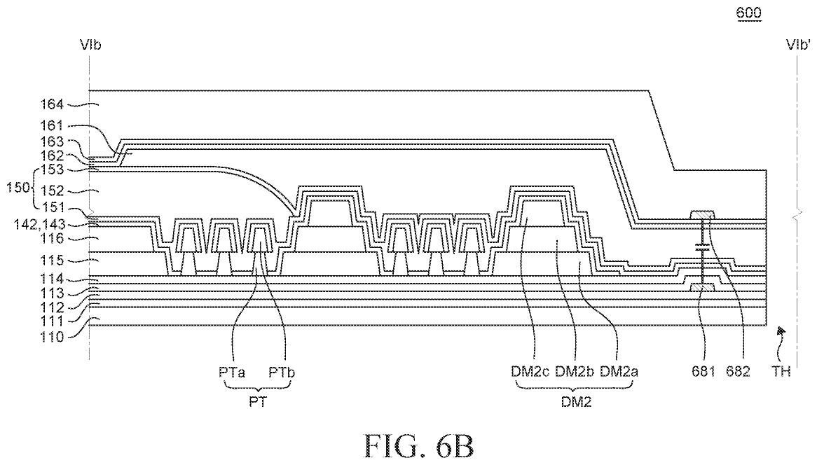

FIG. 6A is an enlarged plan view of a display device according to still another example embodiment of the present disclosure. FIG. 6B is a cross-sectional view of VIb-VIb′ of FIG. 6A. In FIG. 6A, for convenience of description, the active area AA, the second non-active area NA2, a through-hole TH, a third sensing line 681, and a fourth sensing line 682 among components of the display device 100 are illustrated. In addition, in FIG. 6A, the third sensing line 681 is illustrated as a line thinner than the fourth sensing line 682 in order to distinguish the third sensing line 681 and the fourth sensing line 682. Since a display device 600 of FIGS. 6A and 6B is substantially identical to the display device 100 of FIGS. 1 to 3 except that it further includes the third sensing line 681 and the fourth sensing line 682, redundant descriptions thereof will be omitted or briefly provided.

Referring to FIGS. 6A and 6B, the display device 600 can include the through-hole TH, second dams DM2, patterns PT, the third sensing line 681 and the fourth sensing line 682.

The through-hole TH can be formed in the second non-active area NA2. For example, the through-hole TH can be located in a central portion of the second non-active area NA2. The through-hole TH can be formed to physically penetrate the fourth planarization layer 164 from the substrate 110. The through-hole TH can be formed to correspond to a camera. However, the present disclosure is not limited thereto, and an optical sensor can be disposed in the through-hole TH. Light can be easily transmitted from an upper portion of the camera or optical sensor through the through-hole TH.

The second dams DM2 can be disposed to surround the through-hole TH in the second non-active area NA2. The second dams DM2 can be formed in a shape of a looped curve surrounding an outer portion of the through-hole TH. The second dams DM2 can be disposed between the through-hole TH and the active area AA. The second dam DM2 can prevent the foreign material cover layer 152 from overflowing into the through-hole TH. In FIG. 6B, it is illustrated that two second dams DM2 are configured, but the present disclosure is not limited thereto, and the number of second dams DM2 can be changed as needed.

The second dam DM2 can include a first layer DM2a, a second layer DM2b, and a third layer DM2c, but is not limited thereto. The first layer DM2a can be formed of the same material through the same process as the first planarization layer 115, but is not limited thereto. The second layer DM2b can be formed of the same material through the same process as the second planarization layer 116, but is not limited thereto. The third layer DM2c can be formed of the same material through the same process as the bank 117, but is not limited thereto. Further, a material of an insulating layer of the second dam DM2 and the number of layers thereof are not limited thereto.

The patterns PT can be disposed to surround the through-hole TH in the second non-active area NA2. The patterns PT can be formed in a shape of a looped curve surrounding the outer portion of the through-hole TH. The pattern PT can include a first sub-pattern PTa and a second sub-pattern PTb. The first sub-pattern PTa can be formed of the same material through the same process as the first planarization layer 115, but is not limited thereto. The second sub-pattern PTb can be formed of the same material through the same process as the second planarization layer 116, but is not limited thereto. Further, a material of an insulating layer of the pattern PT and the number of layers thereof are not limited thereto.

The patterns PT can be disposed on one side, the other side, or both sides of the second dam DM2. In FIG. 6B, it is illustrated that three patterns PT are disposed on left and right sides of the second dam DM2, but the present disclosure is not limited thereto.

The pattern PT can prevent moisture from penetrating into the active area AA from an inner surface of the through-hole TH through the organic layer 142 or the cathode 143. In particular, the organic layer 142, which is vulnerable to moisture permeation, can have a disconnection structure by the pattern PT. For example, an upper surface of the first sub-pattern PTa of the pattern PT can have a width smaller than that of a lower surface of the second sub-pattern PTb. For example, the organic layer 142 disposed on the pattern PT can be not continuous by the pattern PT and can be disconnected. Therefore, even if moisture penetrates through the organic layer 142, movements of the penetrated moisture into the active area AA can be prevented by a disconnected structure of the organic layer 142.

A third planarization layer 161 can be disposed in the second non-active area NA2. The third planarization layer 161 can be disposed between the encapsulation unit 150 and the second buffer layer 162. The third planarization layer 161 can be an insulating layer for reducing a step between the second non-active area NA2 and the active area AA. Further, the third planarization layer 161 can planarize upper portions of the second dam DM2 and the pattern PT in the second non-active area NA2. The third planarization layer 161 can be formed of an organic material, and can include, for example, a single layer or multiple layers of polyimide or photoacryl, but the present disclosure is not limited thereto.

The third sensing line 681 can be disposed along the outer portion of the through-hole TH. The third sensing line 681 can be disposed adjacent to the end portion of the substrate 110 at an outermost portion of the second non-active area NA2. The third sensing line 681 can be disposed between the second dam DM2 and the through-hole TH. Further, the third sensing line 681 can be disposed between the pattern PT and the through-hole TH. One end and the other end of the third sensing line 681 can be connected to different sensing pads disposed in the pad portion. The third sensing line 681 can detect cracks generated in the second non-active area NA2.

Referring to FIG. 6A, the third sensing line 681 overlaps the fourth sensing line 682 and can be disposed below the fourth sensing line 682, but is not limited thereto, and locations of the third sensing line 681 and the fourth sensing line 682 can be switched. Although only a portion of the third sensing line 681 is illustrated in FIG. 6A, a shape of a remaining portion thereof can correspond to that of the fourth sensing line 682.

The third sensing line 681 can be formed of the same material as one of various conductive components formed in the active area AA. For example, the third sensing line 681 can be formed of the same material through the same process as the gate electrode 122 on the gate insulating layer 112, but is not limited thereto. Accordingly, the third sensing line 681 can detect cracks generated in layers such as the substrate 110, the first buffer layer 111, the gate insulating layer 112, the interlayer insulating layer 113, the passivation layer 114, the first encapsulation layer 151, and the second encapsulation layer 153 that are adjacent to the third sensing line 681. However, embodiments of the present disclosure are not limited thereto. For example, the third sensing line 681 can be formed by the same process as other conductive components other than the gate electrode 122. But embodiments of the present disclosure are not limited thereto.

The fourth sensing line 682 can be disposed along the outer portion of the through-hole TH. The fourth sensing line 682 can be disposed adjacent to the end portion of the substrate 110 at the outermost portion of the second non-active area NA2. The fourth sensing line 682 can be disposed between the second dam DM2 and the through-hole TH. The fourth sensing line 682 can be disposed between the pattern PT and the through-hole TH. One end and the other end of the fourth sensing line 682 can be connected to different sensing pads disposed in the pad portion. The fourth sensing line 682 can detect a crack generated in the second non-active area NA2.

The fourth sensing line 682 can be formed of the same material as one of various conductive components formed in the active area AA, but is not limited thereto. For example, the fourth sensing line 682 can be disposed on the second interlayer insulating layer 163 and formed of the same material through the same process as the first touch electrode 171, the second touch electrode 172, and the second line layer 176, but is not limited thereto. Accordingly, the fourth sensing line 682 can detect cracks generated in layers such as the second buffer layer 162 and the second interlayer insulating layer 163 that are adjacent to the fourth sensing line 682, and embodiments of the present disclosure are not limited thereto. For example, the fourth sensing line 682 can be formed by the same process as other conductive components other than the first touch electrode 171, the second touch electrode 172, and the second line layer 176. But embodiments of the present disclosure are not limited thereto.

Since the third sensing line 681 and the fourth sensing line 682 overlap each other, the third sensing line 681 and the fourth sensing line 682 can form a capacitor. The detection unit can detect strain in a thickness direction of the display device 600 by measuring capacitance between the third sensing line 681 and the fourth sensing line 682. For example, the detection unit can measure capacitance through one of the sensing pads connected to the third sensing line 681 and one of the sensing pads connected to the fourth sensing line 682. Through a measured variation in capacitance, it is possible to determine whether or not defects occur due to compressive strain or tensile strain of the display device 600.

The display device 600 according to still another example embodiment of the present disclosure can also include the first sensing line 181 and the second sensing line 182 overlapping each other at a the first non-active area NA1. The display device 600 can detect cracks and strain in the thickness direction through the first sensing line 181 and the second sensing line 182. For example, the first sensing line 181 and the second sensing line 182 can detect a crack or thickness strain at an outer portion of the display device 600 corresponding to the first non-active area NA1.

The display device 600 according to still another example embodiment of the present disclosure can include the third sensing line 681 and the fourth sensing line 682 overlapping each other. The display device 600 can detect cracks and strain in the thickness direction through the third sensing line 681 and the fourth sensing line 682. In particular, the third sensing line 681 and the fourth sensing line 682 can be disposed in the second non-active area NA2 corresponding to the through-hole TH. In the second non-active area NA2, cracks, compressive strain, tensile strain, and the like can occur due to stress generated when the through-hole TH is formed. Accordingly, the display device 600 according to still another example embodiment of the present disclosure can detect cracks or thickness strain occurring in the second non-active area NA2 through the third sensing line 681 and the fourth sensing line 682. Accordingly, a yield and quality of the display device 600 can be improved by quickly detecting and correcting various defects occurring in the display device 600.

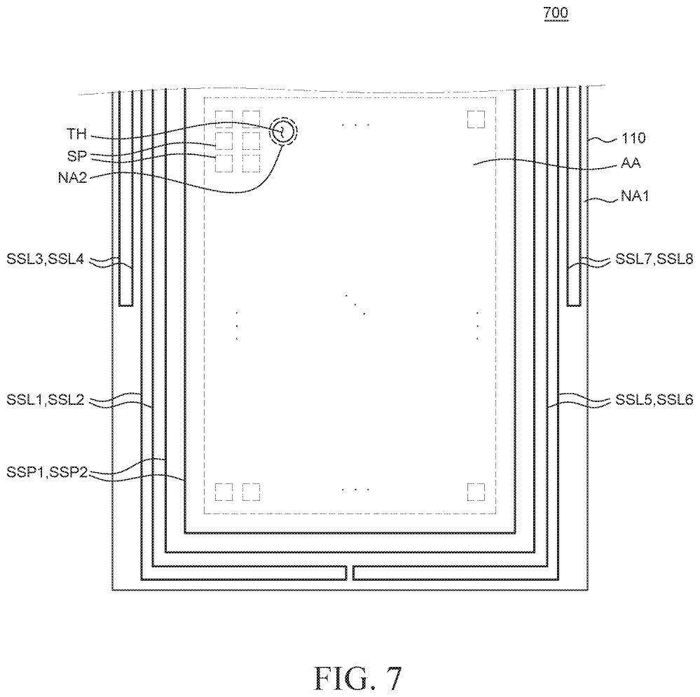

FIG. 7 is a plan view of a display device according to still another example embodiment of the present disclosure. In FIG. 7, provided is a display device 700 that can include the first sub-sensing portions SSP1, the second sub-sensing portions SSP2, and the first, second, third, fourth, fifth, sixth, seventh and eighth sub-sensing lines SSL1, SSL2, SSL3, SSL4, SSL5, SSL6, SSL7 and SSL8. Since the display device 700 of FIG. 7 includes substantially identical elements to the display device 100 of FIG. 1 and the display device 500 of FIG. 5, redundant descriptions thereof will be omitted or briefly provided.

Referring to FIG. 7, the first sub-sensing portions SSP1, the second sub-sensing portions SSP2, and the first, second, third, fourth, fifth, sixth, seventh and eighth sub-sensing lines SSL1, SSL2, SSL3, SSL4, SSL5, SSL6, SSL7 and SSL8 can be used together to provide a more accurate detection of at least one of cracks, strain, delamination, moisture penetration, and warping of the substrate and other layers of the display device 700. For example, detection of the cracks, strain, delamination, moisture penetration, and warping of the display device 700 can be detected using the first sub-sensing portions SSP1, the second sub-sensing portions SSP2, and the first, second, third, fourth, fifth, sixth, seventh and eighth sub-sensing lines SSL1, SSL2, SSL3, SSL4, SSL5, SSL6, SSL7 and SSL8 assigned to detect one of the cracks, strain, delamination, moisture penetration, and warping of the display device 700. For example, the first the first sub-sensing portions SSP1 and the second sub-sensing portions SSP2 can be assigned to more accurately detect delamination or warping of the display device 700, while the first, second, third, fourth, fifth, sixth, seventh and eighth sub-sensing lines SSL1, SSL2, SSL3, SSL4, SSL5, SSL6, SSL7 and SSL8 are assigned to detect cracks or strains. But embodiments of the present disclosure are not limited thereto, as the roles thereof can be reversed or changed.

Also, FIG. 7 shows the placement of the first sub-sensing portions SSP1 and the second sub-sensing portions SSP2 as the innermost elements, the third, fourth, seventh and eight sub-sensing lines SSL3, SSL4, SSL7, SSL8 as the outermost elements, and the first, second, fifth and sixth sub-sensing lines SSL1, SSL2, SSL5 and SSL6 as the intermediate elements. But embodiments of the present disclosure are not limited thereto. For example, the first sub-sensing portions SSP1 and the second sub-sensing portions SSP2 can be provided as the outermost elements in other embodiments of the present disclosure. But embodiments of the present disclosure are not limited thereto, and other arrangements are also possible to achieve compactness and additional functionality.

Referring to FIG. 7, when the third, fourth, seventh and eight sub-sensing lines SSL3, SSL4, SSL7, SSL8 are disposed as the outermost elements, there can be an open area in the first non-active area NA1 that is freed up at lower portion of the display device 700. The open area can accommodate some of the sensing pads or other driving elements of the display device 700 to provide a more efficient use of the area of the display device 700, including the first non-active area NA1. Other sub-sensing lines SSL can be located in the open area.

Further, the first sub-sensing portions SSP1, the second sub-sensing portions SSP2, and the first, second, third, fourth, fifth, sixth, seventh and eighth sub-sensing lines SSL1, SSL2, SSL3, SSL4, SSL5, SSL6, SSL7 and SSL8 can be located on different layers within the first non-active area NA1. For example, with reference to FIG. 3, the first sub-sensing portion SSP1 can be located on the gate insulating layer 112 and the second sub-sensing portion SSP2 can be located on the second interlayer insulating layer 163, but the first, second, third, fourth, fifth, sixth, seventh and eighth sub-sensing lines SSL1, SSL2, SSL3, SSL4, SSL5, SSL6, SSL7 and SSL8 can be located on different layers from each other, as well as from the first sub-sensing portion SSP1 and the second sub-sensing portion SSP2 to adjust the capacitance thereof, which can further provide refinement in sensitivity to the capacitance formed by the first sub-sensing portions SSP1, the second sub-sensing portions SSP2, and the first, second, third, fourth, fifth, sixth, seventh and eighth sub-sensing lines SSL1, SSL2, SSL3, SSL4, SSL5, SSL6, SSL7 and SSL8.

In various embodiments of the present disclosure, lengths of the first, second, third and fourth sensing lines can vary. For example, a length of the first sub-sensing portion SSP1 can be approximately equal to a length of the second sub-sensing portion SSP2. Further, a length of the first sub-sensing line SSL1 can be approximately equal to a length of the second sub-sensing line SSL2. Meanwhile, the length of the first sub-sensing portion SSP1 can be greater than the length of the first sub-sensing line SSL1, but is not limited thereto. Further, a length of the third sensing line can be different from that of the first sub-sensing line SSL1. For example, the length of the third sensing line SSL3 can be less than those of the first sub-sensing portion SSP1 and the first sub-sensing line SSL1, but is not limited thereto.

The example embodiments of the present disclosure can also be described as follows:

According to an aspect of the present disclosure, a display device can include a substrate including an active area and a first non-active area surrounding the active area; a plurality of light emitting elements in the active area; an encapsulation unit covering the plurality of light emitting elements; a plurality of touch electrodes on the encapsulation unit in the active area; a first sensing line surrounding at least a portion of the active area in the first non-active area; and a second sensing line overlapping the first sensing line and configured to form a capacitor with the first sensing line.

A plurality of inorganic insulating layers can be disposed between the first sensing line and the second sensing line.

The display device can further include a dam surrounding the active area in the first non-active area. The first sensing line and the second sensing line can be disposed outside the dam.

The display device can further include a dielectric layer between the first sensing line and the second sensing line. The dielectric layer can be disposed outside the dam.

A side surface of the dielectric layer can be disposed on the same line as a side surface of the substrate.

The display device can further include a low potential power line disposed along a circumference of the substrate at an outer portion of the first non-active area. The first sensing line and the second sensing line can be disposed outside the low potential power line.

The first non-active area can include a pad portion in which a plurality of sensing pads are disposed. Each of one end and the other end of the first sensing line and one end and the other end of the second sensing line can be connected to different sensing pads among the plurality of sensing pads.

An area between the one end and the other end of the first sensing line can be disposed along an outer circumference of the first non-active area.

The first non-active area can include a pad portion in which a plurality of sensing pads are disposed, the first sensing line can include a plurality of first sub-sensing lines that are spaced apart from each other, the second sensing line can include a plurality of second sub-sensing lines that are spaced apart from each other, and each of one ends and the other ends of the plurality of first sub-sensing lines and one ends and the other ends of the plurality of second sub-sensing lines can be connected to different sensing pads among the plurality of sensing pads.

One of the plurality of first sub-sensing lines can extend to an opposite side of the pad portion at one side or the other side of the first non-active area.

One of the plurality of first sub-sensing lines can be disposed to surround a portion of the active area at one side or the other side of the first non-active area.

The first sensing line can include a plurality of first sub-sensing portions connected in parallel, and the second sensing line can include a plurality of second sub-sensing portions connected in parallel.

The display device can further include a plurality of transistors disposed below the plurality of light emitting elements and connected to the plurality of light emitting elements. The first sensing line can be disposed on the same layer as gate electrodes of the plurality of transistors, and the second sensing line can be disposed on the same layer as the plurality of touch electrodes.

The substrate can further include a second non-active area within the active area. The second non-active area can include a through-hole penetrating the substrate.

The display device can further include a third sensing line disposed along an outer portion of the through-hole in the second non-active area; and a fourth sensing line overlapping the third sensing line and configured to form a capacitor with the third sensing line.

The display device can further include a dam disposed to surround the through-hole in the second non-active area. The third sensing line and the fourth sensing line can be disposed between the dam and the through-hole.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area, a first non-active area adjacent the active area, and a second non-active area within the active area, the second non-active area including a through-hole penetrating the substrate;
a plurality of light emitting elements in the active area;
an encapsulation unit covering the plurality of light emitting elements;
a buffer layer on the encapsulation unit;
a plurality of touch electrodes on the buffer layer in the active area;
a first sensing line surrounding at least a portion of the active area, and in the first non-active area; and
a third sensing line disposed along an outer portion of the through-hole in the second non-active area.

2. The display device of claim 1, further comprising a connection electrode between the substrate and the encapsulation unit, the connection electrode including a plurality of holes.

3. The display device of claim 1, further comprising a plurality of touch routing lines on the buffer layer extending from the active area to the first non-active area,
wherein first ends of the plurality of touch routing lines are connected to the plurality of touch electrodes in the active area, and second ends of the plurality of touch routing lines are connected to a plurality of pads in the first non-active area.

4. The display device of claim 1, further comprising a second sensing line surrounding the at least a portion of the active area, and in the first non-active area.

5. The display device of claim 4, wherein the second sensing line overlaps the first sensing line, and is configured to form a capacitor with the first sensing line.

6. The display device of claim 5, further comprising:
a plurality of inorganic insulating layers disposed between the first sensing line and the second sensing line.

7. The display device of claim 5, further comprising:
a dam surrounding the at least a portion of the active area, and in the first non-active area,
wherein the first sensing line and the second sensing line are disposed outside the dam.

8. The display device of claim 7, further comprising:
a dielectric layer in the first non-active area between the first sensing line and the second sensing line,
wherein the dielectric layer is disposed outside the dam.

9. The display device of claim 8, wherein a side surface of the dielectric layer is disposed on a same line as a side surface of the substrate.

10. The display device of claim 5, further comprising:
a low potential power line disposed along a circumference of the substrate at an outer portion of the first non-active area,
wherein the first sensing line and the second sensing line are disposed outside the low potential power line.

11. The display device of claim 5, wherein the first non-active area includes a pad portion in which a plurality of sensing pads are disposed, and
wherein each of a first end and a second end of the first sensing line and a first end and a second end of the second sensing line are connected to different sensing pads among the plurality of sensing pads.

12. The display device of claim 11, wherein an area between the one end and the opposite end of the first sensing line is disposed along an outer circumference of the first non-active area.

13. The display device of claim 5, wherein the first non-active area includes a pad portion in which a plurality of sensing pads are disposed,
wherein the first sensing line includes a plurality of first sub-sensing lines that are spaced apart from each other,
wherein the second sensing line includes a plurality of second sub-sensing lines that are spaced apart from each other, and
wherein each of first ends and second ends of the plurality of first sub-sensing lines and first ends and second ends of the plurality of second sub-sensing lines are connected to different sensing pads among the plurality of sensing pads.

14. The display device of claim 13, wherein one of the plurality of first sub-sensing lines extends to an opposite side of the pad portion at one side or an opposite side of the first non-active area.

15. The display device of claim 13, wherein one of the plurality of first sub-sensing lines is disposed to surround a portion of the active area at one side or an opposite side of the first non-active area.

16. The display device of claim 5, wherein the first sensing line includes a plurality of first sub-sensing portions connected in parallel, and
wherein the second sensing line includes a plurality of second sub-sensing portions connected in parallel.

17. The display device of claim 5, further comprising:
a plurality of transistors disposed below the plurality of light emitting elements and connected to the plurality of light emitting elements,
wherein the first sensing line is disposed on a same layer as gate electrodes of the plurality of transistors, and
wherein the second sensing line is disposed on a same layer as the plurality of touch electrodes.

18. The display device of claim 5, further comprising:
a detection unit including the first sensing line and the second sensing line,
wherein the detection unit is configured to detect at least one of a strain and a crack in the display device by measuring the capacitance between the first sensing line and the second sensing line.

19. The display device of claim 1, further comprising:
a fourth sensing line disposed along the outer portion of the through-hole in the second non-active area.

20. The display device of claim 19, wherein the fourth sensing line overlaps the third sensing line and is configured to form a capacitor with the third sensing line.

21. The display device of claim 20, further comprising:
a dam disposed to surround the through-hole in the second non-active area,
wherein the third sensing line and the fourth sensing line are disposed between the dam and the through-hole.

22. A display device, comprising:
a substrate including an active area, a first non-active area adjacent the active area, and a second non-active area within the active area, the second non-active area including a through hole;
a plurality of light emitting elements in the active area;
an encapsulation unit covering the plurality of light emitting elements;
a first sensing line extending in the first non-active area; and
a third sensing line extending in the second non-active area,
wherein the first sensing line includes a first sub-sensing portion and a first sub-sensing line,
wherein the first sub-sensing portion and the first sub-sensing line have different lengths, and
wherein a length of the third sensing line is different from a length of the first sub-sensing line.

23. The display device of claim 22, further comprising a second sensing line in the first non-active area, and overlapping the first sensing line to form a capacitor with the first sensing line; and
a fourth sensing line in the second non-active area, and overlapping the third sensing line to form a capacitor with the third sensing line,
wherein the second sensing line includes a second sub-sensing portion and a second sub-sensing line.

24. The display device of claim 23, wherein a length of the first sub-sensing portion is approximately equal to a length of the second sub-sensing portion, and
wherein the length of the first sub-sensing line is approximately equal to a length of the second sub-sensing line.

25. The display device of claim 23, wherein a length of the first sub-sensing portion is greater than the length of the first sub-sensing line.

26. The display device of claim 23, wherein the first sub-sensing portion and the first sub-sensing line are disposed on a same first layer, and
wherein the second sub-sensing portion and the second sub-sensing line are disposed on a same second layer.

27. The display device of claim 23, wherein the first sub-sensing portion, the first sub-sensing line, the second sub-sensing portion and the second sub-sensing line are disposed on different layers.

28. The display device of claim 23, wherein the first sub-sensing portion and the second sub-sensing portion are located inward to the first sub-sensing line and the second sub-sensing line in the display device.

29. The display device of claim 23, wherein the length of the third sensing line is less than a length of the first sub-sensing portion and the length of the first sub-sensing line.
